(19) United States
(12) Patent Application Publication
(10) Pub. No.: US 2024/0282251 A1
(43) Pub. Date: Aug. 22, 2024

(54) DISPLAY APPARATUS

(71) Applicant: LG DISPLAY CO., LTD., Seoul (KR)

(72) Inventor: KiTae KIM, Paju-si (KR)

(73) Assignee: LG DISPLAY CO., LTD., Seoul (KR)

(21) Appl. No.: 18/440,064

(22) Filed: Feb. 13, 2024

(30) Foreign Application Priority Data
Feb. 20, 2023 (KR) 10-2023-0022276

(51) Int. Cl. G09G 3/3208

(52) U.S. Cl. CPC G09G 3/3208

(57) ABSTRACT

A display apparatus may comprise a substrate including an emission portion and a non-emission portion adjacent to the emission portion, a planarization layer disposed on the substrate, the planarization layer including a groove disposed in the non-emission portion, a first electrode disposed in the emission portion and the non-emission portion, and a bank disposed in the non-emission portion and provided in a partial region on the first electrode and the groove.

### CROSS-REFERENCE TO RELATED APPLICATIONS

This application claims the benefit of the Korean Patent Application No. 10-2023-0022276 filed on Feb. 20, 2023, which is hereby incorporated by reference as if fully set forth herein.

### TECHNICAL FIELD

The present disclosure relates to a display apparatus, and more particularly, to a display apparatus which prevents a thin film transistor from being degraded to solve a problem where luminance is reduced.

### BACKGROUND

Recent display apparatuses, which may display various information and may simultaneously interact with a user who watches corresponding information, need various sizes, various shapes, and various functions.

Such display apparatuses include liquid crystal display (LCD) apparatuses, electrophoretic display (EPD) apparatuses, and light emitting diode (LED) display apparatuses.

Display apparatuses may include a plurality of gate lines and a plurality of data lines, and the gate line and/or the data line may intersect each other to define a pixel area. The pixel area may include one or more thin film transistors (TFTs), and the TFT may adjust a level of a voltage or a current applied to an organic light emitting diode for each pixel area to control the amount of light emitted from the pixel area.

Improving of luminance of display apparatuses is a main research project, but TFTs may be vulnerable to light and may thus be degraded by external light, internal reflected light, or scattered light. Due to this, the luminance of display apparatuses may be reduced, causing a problem where the luminance of display apparatuses is lowered when a user sees a display apparatus.

Therefore, various reviews are being done for solving a problem where the luminance of display apparatuses is reduced, but research and development for solving the problem are insufficient and are more needed.

### SUMMARY

Accordingly, the present disclosure is directed to providing a display apparatus that substantially obviates one or more problems due to limitations and disadvantages of the related art.

An aspect of the present disclosure is directed to providing a display apparatus which includes a planarization layer including a groove and a bank disposed in the groove so as to solve a problem where the luminance of the display apparatus is reduced.

Another aspect of the present disclosure is directed to providing a display apparatus which includes a black material so as to solve a problem where the luminance of the display apparatus is reduced.

Another aspect of the present disclosure is directed to providing a display apparatus in which a planarization layer including a groove and a bank filled in the groove are provided to solve a problem where a thin film transistor is degraded by light, and thus, the thin film transistor is normally driven, thereby enhancing a sense of beauty, lifetime, and reliability.

A display apparatus according to the present disclosure may include a substrate including an emission portion of a subpixel and a non-emission portion adjacent to the emission portion, a planarization layer disposed on the substrate, the planarization layer including a groove disposed in the non-emission portion, a first electrode disposed in the emission portion and the non-emission portion, and a bank disposed in the non-emission portion and provided in a partial region of the first electrode and in the groove.

A display apparatus according to the present disclosure may include a substrate including an emission portion of a subpixel and a non-emission portion adjacent to the emission portion, a planarization layer disposed on the substrate, the planarization layer including a groove disposed in the non-emission portion, a first electrode disposed in the emission portion and the non-emission portion, a first bank disposed in the non-emission portion and filled in the groove, and a second bank disposed on the first bank.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate aspects of the disclosure and together with the description serve to explain the principle of the disclosure. In the drawings:

FIG. 1 is a diagram illustrating a display apparatus according to an aspect of the present disclosure;

FIG. 2 is a plan view of a display apparatus according to an aspect of the present disclosure;

FIG. 3 is a circuit diagram illustrating pixel driving of a display apparatus according to an aspect of the present disclosure;

FIG. 4 is a diagram illustrating the arrangement of an emission portion and a non-emission portion of a display apparatus according to an aspect of the present disclosure;

FIG. 5 is a cross-sectional view taken along line I-I′ of FIG. 4 according to an aspect of the present disclosure;

FIG. 6 is a cross-sectional view taken along line II-II′ of FIG. 4 according to an aspect of the present disclosure;

FIG. 7 is a cross-sectional view of a display apparatus according to another aspect of the present disclosure; and

FIG. 8 is a cross-sectional view of an emission unit according to an aspect of the present disclosure.

### DETAILED DESCRIPTION

Reference is now made in detail to aspects of the present disclosure, examples of which may be illustrated in the accompanying drawings. In the following description, when a detailed description of well-known functions or configurations may unnecessarily obscure aspects of the present disclosure, the detailed description thereof may be omitted for brevity. The progression, sequence or order of processing steps and/or operations described is an example; however, the sequence of steps and/or operations is not limited to that set forth herein and may be changed, with the exception of steps and/or operations necessarily occurring in a particular order.

Unless stated otherwise, like reference numerals may refer to like elements throughout even when they are shown in different drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof will be clarified through following aspects described with reference to the accompanying drawings. The present disclosure may, however, be embodied in different forms and should not be construed as limited to the aspects set forth herein. Rather, these aspects are provided so that this disclosure will be thorough and complete, and will fully convey the scope of the present disclosure to those skilled in the art. Furthermore, the present disclosure is only defined by scopes of claims.

The shapes, sizes, areas, ratios, angles, numbers, and the like disclosed in the drawings for describing aspects of the present disclosure are merely examples, and thus, the present disclosure is not limited to the illustrated details.

When the term “comprise,” “have,” “include,” “contain,” “constitute,” “make up of,” “formed of,” or the like is used, one or more other elements may be added unless a term such as “only” or the like is used. The terms used in the present disclosure are merely used to describe particular aspects, and are not intended to limit the scope of the present disclosure. The terms used herein are merely used to describe example aspects, and are not intended to limit the scope of the present disclosure. The terms of a singular form may include plural forms unless the context clearly indicates otherwise, and vice versa. The word “exemplary” is used to mean serving as an example or illustration. Embodiments are examples. Aspects are example aspects. Any implementation described herein as an “example” is not necessarily to be construed as preferred or advantageous over other implementations.

In one or more aspects, an element, feature, or corresponding information (e. g., a level, range, dimension, size, or the like) is construed as including an error or tolerance range even where no explicit description of such an error or tolerance range is provided. An error or tolerance range may be caused by various factors (e. g., process factors, internal or external impact, noise, or the like). Further, the term “may” encompasses all the meanings of the term “may.”

In describing a positional relationship, where the positional relationship between two parts is described, for example, using “on,” “over,” “under,” “above,” “below,” “beneath,” “near,” “close to,” or “adjacent to,” “beside,” “next to,” or the like, one or more other parts may be located between the two parts unless a more limiting term, such as “immediate(ly),” “direct(ly),” or “close(ly),” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

In describing a temporal relationship, when the temporal order is described as, for example, “after,” “subsequent,” “next,” “before,” “preceding,” “prior to,” or the like, a case that is not consecutive or not sequential may be included unless a more limiting term, such as “just,” “immediate(ly),” or “direct(ly),” is used.

It is understood that, although the term “first,” “second,” or the like may be used herein to describe various elements, these elements should not be limited by these terms. These terms are only used to distinguish one element from another. For example, a first element could be a second element, and, similarly, a second element could be a first element, without departing from the scope of the present disclosure. Furthermore, the first element, the second element, and the like may be arbitrarily named according to the convenience of those skilled in the art without departing from the scope of the present disclosure. The terms “first,” “second,” and the like may be used to distinguish components from each other, but the functions or structures of the components are not limited by ordinal numbers or component names in front of the components.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of elements.

For the expression that an element or layer is “connected,” “coupled,” or “adhered” to another element or layer the element or layer may not only be directly connected, coupled, or adhered to another element or layer, but also be indirectly connected, coupled, or adhered to another element or layer with one or more intervening elements or layers disposed or interposed between the elements or layers, unless otherwise specified.

For the expression that an element or layer “contacts,” “overlaps,” or the like with another element or layer, the element or layer may not only directly contact, overlap, or the like with another element or layer, but also indirectly contact, overlap, or the like with another element or layer with one or more intervening elements or layers disposed or interposed between the elements or layers, unless otherwise specified.

The term “at least one” should be understood as including any and all combinations of one or more of the associated listed items. For example, the meaning of “at least one of a first item, a second item, and a third item” denotes the combination of items proposed from two or more of the first item, the second item, and the third item as well as only one of the first item, the second item, or the third item.

The expression of a first element, a second elements “and/or” a third element should be understood as one of the first, second and third elements or as any or all combinations of the first, second and third elements. By way of example, A, B and/or C may refer to only A; only B; only C; any or some combination of A, B, and C; or all of A, B, and C. Furthermore, an expression “element A/element B” may be understood as element A and/or element B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

Features of various aspects of the present disclosure may be partially or overall coupled to or combined with each other, and may be variously inter-operated, linked or driven together. The aspects of the present disclosure may be carried out independently from each other or may be carried out together in co-dependent or related relationship. In one or more aspects, the components of each apparatus according to various aspects of the present disclosure are operatively coupled and configured.

Unless otherwise defined, the terms (including technical and scientific terms) used herein have the same meaning as commonly understood by one of ordinary skill in the art to which example aspects belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

In some aspects of the disclosure, an apparatus may include a display device such as a liquid crystal module (LCM) including a display panel and a driver for driving the display panel, and an organic light emitting display (OLED) module. The apparatus may include a laptop computer, television, computer monitor, vehicle or automotive apparatus, or other type of vehicle that is a complete product or final product including LCM, OLED module, etc. The apparatus may also include a set electronic apparatus or a set device, such as an equipment apparatus, a mobile electronic apparatus such as a smartphone or an electronic pad, etc.

Therefore, the apparatus in this specification may include the display device such as an LCM, an OLED module, etc., and an application product including an LCM, an OLED module, etc., or a set device that is a device for end consumers.

The display panel described in the aspects of the present specification includes all types of display panels, such as liquid crystal display panels, organic light emitting diode (OLED) display panels, and electroluminescent display panels. It may be used, and the examples are not limited thereto. The display panel applied to the display device according to the aspect of the present disclosure is not limited to the shape or size of the display panel.

Hereinafter, aspects of a display apparatus according to various example aspects of the present disclosure will be described in detail with reference to the accompanying drawings. With respect to reference numerals to elements of each of the drawings, although the same elements may be illustrated in other drawings, like reference numerals may refer to like elements unless stated otherwise. In addition, for convenience of description, a scale, dimension, size, and thickness of each of the elements illustrated in the accompanying drawings may differ from an actual scale, dimension, size, and thickness, and thus, aspects of the present disclosure are not limited to a scale, dimension, size, and thickness illustrated in the drawings.

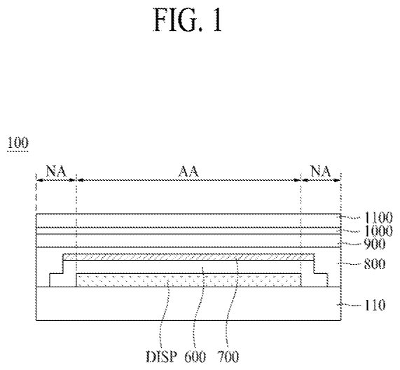

FIG. 1 is a diagram illustrating a display apparatus 100 according to an aspect of the present disclosure.

Referring to FIG. 1, the display apparatus 100 may include a substrate 110 which includes a display area AA and a non-display area NA.

A display driving part DISP including a thin film transistor (TFT) and a light emitting device layer may be disposed on the substrate 110. An encapsulation layer 600 and a touch sensor layer 700 may be disposed on the display driving part DISP.

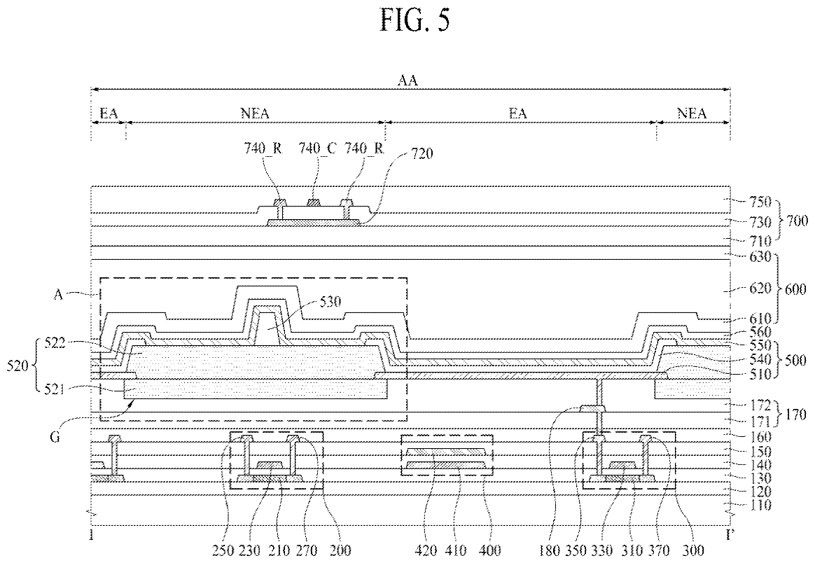

The display driving part DISP, the encapsulation layer 600, and the touch sensor layer 700 will be described below in detail with reference to FIG. 5.

A polarizer 900 may be disposed on the touch sensor layer 700. The polarizer 900 may selectively transmit light to decrease the reflection of external light incident on the display apparatus. For example, the display apparatus may include various metal materials applied to a TFT, a light emitting device layer, and various lines. The external light incident on the display apparatus may be reflected from the metal material, and due to the reflection of the external light, the visibility of the display apparatus 100 may be reduced. Accordingly, the polarizer 900 may be disposed at one surface of the display apparatus 100, to prevent the reflection of the external light and may increase the outdoor visibility of the display apparatus 100.

The polarizer 900 may be omitted based on a structure of the display apparatus 100.

A first adhesive layer 800 may be disposed between the touch sensor layer 700 and the polarizer 900. The touch sensor layer 700 may be attached on the polarizer 900 by using the first adhesive layer 800.

The first adhesive layer 800 may include a material having adhesive properties, and for example, may include an optically clear adhesive (OCA) or a pressure sensitive adhesive (PSA). However, aspects of the present disclosure are not limited thereto.

The first adhesive layer 800 may protect the display driving part DISP from external water, oxygen, or particles along with the encapsulation layer 600.

A front member 1100 may be disposed on the polarizer 900. The front member 1100 may protect the polarizer 900, the display driving part DISP, and the touch sensor layer 700, which are disposed under the front member 1100, from external impact, moisture, and heat. The front member 1100 may include a material having an impact resistance and light transmissivity. For example, the front member 1100 may be a substrate including glass or may be a film including a plastic material such as polymethylmethacrylate (PMMA), polyimide (PI), or polyethylene terephthalate (PET), but aspects of the present disclosure are not limited thereto. Also, the front member 1100 may be referred to as various terms such as a cover window, a window cover, or a cover glass, but aspects of the present disclosure are not limited thereto.

The front member 1100 may be bonded to the substrate 110 by a bonding process after a manufacturing process of elements disposed on the substrate 110 is completed.

A second adhesive layer 1000 may be disposed between the polarizer 900 and the front member 1100. The polarizer 900 may be attached on the front member 1100 by using the second adhesive layer 1000.

The second adhesive layer 1000 may include a material having adhesive properties, and for example, may include an OCA or a PSA. However, aspects of the present disclosure are not limited thereto.

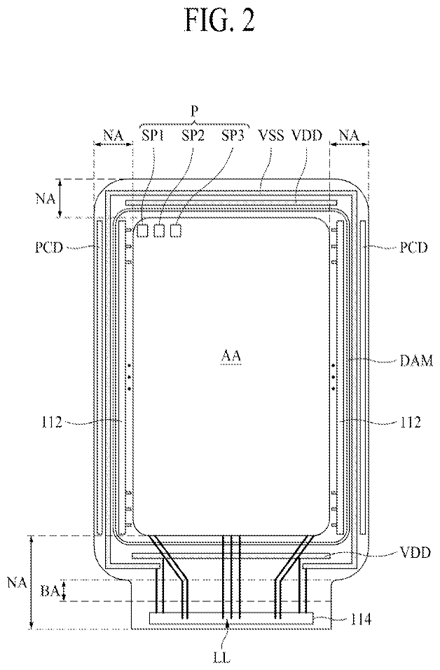

Hereinafter, a display driving part will be described with reference to FIGS. 2 to 5.

FIG. 2 is a plan view of a display apparatus according to an aspect of the present disclosure.

Referring to FIG. 2, the substrate 110 may include a display area (or an active area) AA and a non-display area (or a non-active area) NA surrounding the display area AA. The non-display area NA of the substrate 110 may be disposed adjacent to the display area AA and outward from the display area AA.

The display area AA may include a plurality of pixels P to display an image.

The pixel P disposed on the display area AA may include a plurality of subpixels SP1 to SP3. Each of the plurality of subpixels SP1 to SP3 may be an individual unit for emitting light, and the plurality of subpixels SP1 to SP3 may emit red light, green light, blue light, and/or white light. However, aspects of the present disclosure are not limited thereto.

The display area AA may include an organic light emitting device (or an organic light emitting diode). Each of the plurality of subpixels SP1 to SP3 may include a light emitting device layer for displaying an image and a TFT for driving the light emitting device layer.

One subpixel SP may include a plurality of TFTs T, a capacitor C, and a plurality of lines. For example, one subpixel SP may be provided in a structure including two TFTs and one capacitor, also referred to as 2T1C. The subpixel is not limited to this configuration and may be provided in 3T1C, 4T1C, 5T1C, 6T1C, 7T1C, 3T2C, 4T2C, 5T2C, 6T2C, 7T2C, and 8T2C and may be implemented based on a structure and a type of a TFT.

The non-display area does not display an image and may include various driving circuits and lines for driving a plurality of subpixels SP disposed in the display area AA. The non-display area NA does not display an image, and thus, a partial region of the non-display area NA of the substrate 110 may be bent, thereby decreasing the non-display area NA (for example, a bezel area).

The non-display area NA, as illustrated in FIG. 2, may be disposed outside the display area AA. For example, the non-display area NA may surround the display area AA. The non-display area NA may extend from the display area AA. Alternatively, the non-display area NA may be where a plurality of subpixels SP are not provided, but aspects of the present disclosure are not limited thereto.

In FIG. 2, the non-display area NA surrounds the display area AA having a tetragonal shape, but a shape of the display area AA and the arrangement and shape of the non-display area NA adjacent to the display area AA are not limited to an example illustrated in FIG. 2. The display area AA and the non-display area NA may each be a type suitable for a design of an electronic device equipped with the display apparatus 100. When the display apparatus 100 is a display apparatus of a wearable device such as a wristwatch, the display apparatus 100 may have a circular shape, and concepts of aspects of the present disclosure may also be applied to a free-form display apparatus applicable to a vehicular dashboard. A shape of the display area AA may be a pentagonal shape, hexagonal shape, a circular shape, or an oval shape, but aspects of the present disclosure are not limited thereto.

The non-display area NA includes various lines and driving circuits for driving the plurality of subpixels SP1 to SP3 in the display area AA. For example, various integrated circuits (ICs) and driving circuits such as a gate driver and a data driver may be disposed in the non-display area NA. The non-display area NA may also be referred to as a bezel area, but the terms are not limited thereto.

The display apparatus 100 according to the present disclosure may include various additional elements for generating various signals or driving the plurality of subpixels SP1 to SP3 of the display area AA. For example, a driving circuit for controlling (or driving) the plurality of subpixels SP1 to SP3 may include a gate driver 112, data signal lines, a multiplexer (MUX), an electrostatic discharge (ESD) circuit, a power line, an inverter circuit, and a link line LL. The power lines may be a high level voltage line VDD and/or a low level voltage line VSS, but aspects of the present disclosure are not limited thereto. The display apparatus 100 may include an additional element, in addition to an element for driving the plurality of subpixels SP1 to SP3. For example, the display apparatus 100 may include additional elements which provide a touch sensing function, a user authentication function (for example, fingerprint recognition), a multi-level pressure sensing function, and a tactile feedback function, but aspects of the present disclosure are not limited thereto. The additional elements described above may be provided by an external circuit connected with a link interface or may be the non-display area NA, but aspects of the present disclosure are not limited thereto.

A pad part 114 may be disposed at a side of the non-display area NA. The pad part 114 may be a metal pattern that is bonded to an external module (for example, a flexible printed circuit board (FPCB) and a chip on film (COF)). The pad part 114 is illustrated as being disposed at one side of the substrate 110, but the shape and arrangement of the pad part 114 are not limited thereto.

The gate driver 112 which provides a gate signal to a TFT may be disposed at the other side of the non-display area NA. The gate driver 112 may include various gate driving circuits, and the gate driving circuits may be provided directly on the substrate 110. In this case, the gate driver 112 may be a gate in panel (GIP), but the terms are not limited thereto.

The gate driver 112 may be disposed between the display area AA and a dam DAM. The high level voltage line VDD, the low level voltage line VSS, the multiplexer (MUX), the ESD circuit, and the link line LL may be disposed between the pad part 114 of the non-display area NA and the display arear AA, but aspects of the present disclosure are not limited thereto.

The high level voltage line VDD, the low level voltage line VSS, the multiplexer (MUX), and the link line LL may be disposed between the display area AA and a bending area BA. The high level voltage line VDD, the low level voltage line VSS, the multiplexer (MUX), and the link line LL may be disposed between the display arear AA and an adjacent non-bending area

The link line LL may be disposed in a portion of the non-display area NA. The link line LL may be disposed in the bending area BA of the display apparatus and a non-bending area adjacent to the bending area BA.

The link line LL may transfer a signal, which is supplied from an external module bonded to the pad part 114, to the display area AA or a circuit unit such as the gate driver 112. For example, various signals and voltages such as a gate signal, a data signal, a high level voltage, and a low level voltage may be transferred through the link line LL.

The link line LL may be divided into a power link line and/or a signal link line, based on a transferred voltage and/or image signal.

The power link line may transfer a voltage, which is supplied from the external module, to the display area AA. The power link line may be connected with the low level voltage line VSS, the high level voltage line VDD, and a gate low voltage line and/or a gate high voltage line included in the gate driver, but aspects of the present disclosure are not limited thereto. The power link line may be disposed on a first planarization layer 171.

The signal link line may transfer a signal, which is supplied from the external module, to the display area AA. The signal link line may be connected with a scan line and/or a data line, but aspects of the present disclosure are not limited thereto.

The dam DAM may be disposed in the non-display area NA to surround all or a portion of the display area AA. The dam DAM may be disposed adjacent to the display area AA and outward from the display area AA.

The dam DAM may be disposed along a peripheral portion of the display area AA to control a flow of a layer, including an organic material, of an encapsulation layer disposed on the light emitting device layer during manufacturing. The dam DAM may be provided as one or in plurality.

A panel crack detector line PCD may be further disposed at a portion of the non-display area NA of the substrate 110.

The panel crack detector line PCD may be disposed between an end point (or an end) of the substrate 110 and the dam DAM. Alternatively, the panel crack detector line PCD may be disposed under the dam DAM and may overlap at least a portion of the dam DAM.

The panel crack detector line PCD may be disposed outside the display apparatus and may detect a defect such as a crack occurring in an outer portion of the display apparatus.

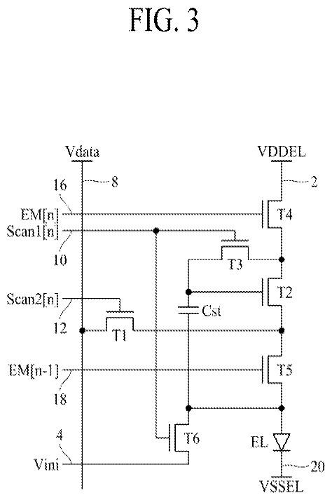

FIG. 3 is a circuit diagram illustrating pixel driving of a display apparatus according to an aspect of the present disclosure.

Referring to FIG. 3, in the display apparatus according to an aspect of the present disclosure, a pixel driving circuit (or a pixel circuit) may include six TFTs T1 to T6 and one storage capacitor Cst. In some aspects, one of the six TFTs T1 to T6 may be a driving TFT T2, and the other TFTs may be switching TFTs T1 and T3 to T6 for compensating for a characteristic (for example, a threshold voltage and/or mobility) of the driving TFT T2. However, aspects of the present disclosure are not limited thereto.

A first switch TFT T1 may be turned on by a second scan signal Scan2[n] supplied through a second gate line 12 and may transfer a data voltage Vdata, supplied through a data line 8, to a first electrode (or a source electrode) of a driving TFT T2 and a first electrode (or a source electrode) of a fifth switching TFT T5.

A third switching TFT T3 may be turned on by a first scan signal Scan1 [n] supplied through a first gate line 10 and may connect a gate electrode and a second electrode (or a drain electrode) of the driving TFT T2 with each other in a diode structure. In this case, the third switching TFT T3 may operate during a sampling period where a threshold voltage Vth of the driving TFT T2 is stored in the capacitor Cst.

Therefore, the third switching TFT T3 may affect a gate voltage of the driving TFT T2 during the sampling period, and thus, a threshold voltage Vth of the third switching TFT T3 may vary the gate voltage of the driving TFT T2. Accordingly, a compensation voltage corresponding to the threshold voltage Vth of the driving TFT T2 stored in the capacitor Cst during the sampling period may affect a threshold voltage Vth of the third switching TFT T3. When the third switching TFT T3 includes an oxide semiconductor layer, the threshold voltage Vth of the third switching TFT T3 may degrade or change based on external light that is incident on the display apparatus from the outside, internal reflected light obtained through reflection by a metal line and a metal electrode disposed in the display apparatus, or scattered light. Therefore, the amount of current flowing in the driving TFT T2 may be change based on the threshold voltage Vth of the third switching TFT T3, and the luminance of a light emitting device layer EL emitting light based on a current flowing in the driving TFT T2 may change. Accordingly, the amount of current flowing in the driving TFT T2 or the luminance of the light emitting device layer EL may change with a large dynamic range based on the threshold voltage Vth of the third switching TFT T3.

A fourth switching TFT T4 may be turned on by an emission control signal EM[n] supplied through a first emission control line 16 and may transfer a first source voltage VDDEL, supplied through a first power line 2, to a source electrode of the driving TFT T2.

The fifth switching TFT T5 may be turned on by an emission control signal EM[n−1] supplied through a second emission control line 18 and may electrically connect a drain electrode of the driving TFT T2 with an anode electrode of the light emitting device layer EL.

A sixth switching TFT T6 may be turned on by a first scan signal Scan1 [n] supplied through the first gate line 10 and may transfer an initialization voltage Vini, supplied through an initialization voltage line 4, to a drain electrode of the fifth switching TFT T5.

The storage capacitor Cst may be connected between a gate electrode of the driving TFT T2 and a drain electrode of the sixth switching TFT T6, and a difference voltage between the high level source voltage VDDEL and a data voltage “Vdata+Vth,” which is obtained through the compensation of the threshold voltage Vth of the driving TFT T2, may be charged in the storage capacitor Cst and may be supplied as a driving voltage of the driving TFT T2.

The driving TFT T2 may control a current flowing to the light emitting device layer EL through the fifth switching TFT T5 based on the driving voltage charged in the storage capacitor Cst, and thus, may control the emission intensity of the light emitting device layer EL.

The light emitting device layer EL may include an anode electrode that is connected with a drain electrode of the driving TFT T2 through the fifth switching TFT T5, a cathode which is connected with a second power line 20 transferring a second source voltage VSSEL, and an emission layer between the anode and the cathode.

For example, in the present disclosure, the driving TFT T2 may include an oxide semiconductor layer. Also, the third switching TFT T3 of switching TFTs electrically connected with the driving TFT T2 may include an oxide semiconductor layer. Furthermore, at least one of the other switching TFTs T1 and T4 to T6 for internal compensation may include a polycrystalline silicon semiconductor layer and/or an oxide semiconductor layer.

The third switching TFT T3, which connects the gate electrode and the source electrode of the driving TFT T2 in a diode structure, may largely change based on a variation of the threshold voltage Vth thereof compared to the other TFTs T1, T2, T4, T5, and T6. For example, the amount of variation of a current ΔIoled flowing in the light emitting device may increase or decrease in proportion to a variation of the threshold voltage Vth of the third switching TFT T3. For example, the display apparatus 100 may denote that the sensitivity of luminance is high, based on a variation of the threshold voltage Vth of the third switching TFT T3.

In an aspect of the present disclosure, the display apparatus may include a planarization layer including a groove and a bank disposed in the groove to prevent a TFT (for example, the third switching TFT T3) from being degraded by light. For example, light that degrades the display apparatus can be external light, internal reflected light, or scattered light. A degradation in the third switching TFT T3 caused by light may be considerably reduced, thereby preventing luminance degradation of the display apparatus.

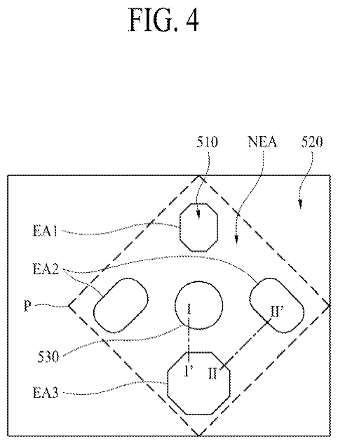

FIG. 4 is a diagram illustrating the arrangement of an emission portion and a non-emission portion of a display apparatus according to an aspect of the present disclosure.

The display area AA of the substrate 110 may include an emission portion EA and a non-emission portion NEA disposed between adjacent emission portions.

The emission portion EA comprises a light emitting device layer that emits light in the subpixel SP, and each subpixel may include an emission portion. A plurality of emission portion EAs may be provided on the substrate 110, and the plurality of emission portions may be separated. The non-emission portion NEA may be disposed to surround the emission portion.

The emission portion EA emits light from an emission layer to the outside. Referring to FIG. 5, the emission portion EA may not include a bank 520.

The non-emission portion NEA does not emit light and includes supporting structures. For example, the non-emission portion NEA may include a bank 520.

A plurality of emission portions emitting lights of different colors may be disposed in the emission portion EA. For example, the emission portion EA may include a first emission portion EA1 emitting red light, a second emission portion EA2 emitting green light, and a third emission portion EA3 emitting blue light. Alternatively, the emission portion EA may include a white emission portion, but aspects of the present disclosure are not limited thereto.

Each emission portion EA may be formed in a specific shape as in FIG. 4 and may be arranged in a specific form, but the emission portions EA of the display apparatus 100 according to the present disclosure may be arranged in various shapes and forms. For example, an exemplary shape of each emission portion EA may be a tetragonal shape, a pentagonal shape, a hexagonal shape, an octagonal shape, a circular shape, or an oval shape, but aspects of the present disclosure are not limited thereto.

One pixel P may include a plurality of subpixels or emission portions emitting lights having the same color as in FIG. 4. For example, a second subpixel SP2 or a second emission portion EA2 may be provided as at least two or more in one pixel P.

In some aspects, a third emission portion EA3 may be greater in area than the other emission portions. The third emission portion EA3 may be disposed all over the other emission portion. For example, the third emission portion EA3 may overlap at least a portion of each of the first emission portion EA1 and the second emission portion EA2.

A spacer 530 may be disposed to have a predetermined distance to a plurality of subpixels SP. For example, the spacer 530 may be separated from the plurality of subpixels SP by the predetermined distance and may be disposed to be surrounded by the plurality of subpixels SP. For example, as illustrated in FIG. 4, four subpixels may surround one spacer.

The spacer 530 may be substantially disposed at a center of a plurality of subpixels emitting light having at least one same color.

The spacer 530 may buffer an empty space between an upper substrate and the substrate 110 where the light emitting device layer 500 is formed, and thus, may minimize the damage of the display apparatus 100 caused by an external impact.

In addition, the spacer 530 may protect the light emitting device layer 500. For example, a fine metal mask (FMM) may be used in forming the light emitting device layer 500. The FMM may be sagged due to a weight in performing a process. Therefore, the spacer 530 may be disposed and may contact the FMM, thereby preventing the FMM from directly contacting the bank 520 to damage and/or deform the bank 520.

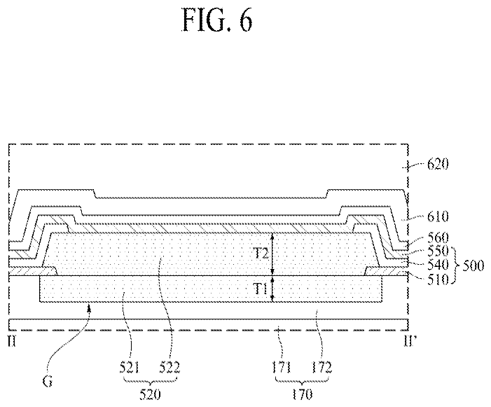

Hereinafter, a cross-sectional structure according to the present disclosure will be described in detail with reference to FIGS. 5 and 6.

FIG. 5 is a cross-sectional view taken along line I-I′ of FIG. 4 according to an aspect of the present disclosure. FIG. 5 is a diagram illustrating a portion of a cross-sectional structure of one subpixel SP disposed in the display area illustrated in FIG. 4. The subpixel SP may include a light emitting device layer 500 for displaying an image and a first TFT 200 and a second TFT 300 for driving the light emitting device layer 500.

The substrate 110 may support various elements of the display apparatus. The substrate 110 may include rigid material such as glass or a flexible material such as plastic.

For example, the substrate 110 may include one or more of polyimide (PI), polymethylmethacrylate (PMMA), polyethylene terephthalate (PET), polyethersulfone, and polycarbonate (PC), but aspects of the present disclosure are not limited thereto.

When the substrate 110 includes polyimide, the substrate 110 may include two polyimide layers. An inorganic layer may be further disposed between the two polyimide layers.

A device and a function layer formed on the substrate 110, for example, may include a switching TFT, a driving TFT connected with the switching TFT, an organic light emitting device connected with the driving TFT, and a protection layer, but aspects of the present disclosure are not limited thereto.

The buffer layer 120 may be disposed on an entire surface of the substrate 110.

The buffer layer 120 may be formed on the substrate 110 and may prevent an internal material of the substrate 110 from moving toward a TFT or a semiconductor layer.

The buffer layer 120 may include an insulating inorganic material such as nitride silicon (SiNx) or oxide silicon (SiOx), and moreover, may include an insulating organic material, but aspects of the present disclosure are not limited thereto.

The buffer layer 120 may be configured as a single layer or a multilayer of SiNx or SiOx, but aspects of the present disclosure are not limited thereto. In a case where the buffer layer 120 is configured as a multilayer, the buffer layer 120 may be formed by alternately stacking SiNx and SiOx, but aspects of the present disclosure are not limited thereto.

The buffer layer 120 may be a first buffer layer, but aspects of the present disclosure are not limited thereto.

The buffer layer 120 may be omitted based on the kind and material of the substrate 110 and the structure and type of TFT.

A first TFT 200 and a second TFT 300 may be disposed on the buffer layer 120. The first TFT 220 may be a switching TFT, and the second TFT 300 may be a driving TFT.

The first TFT 200 may include a first semiconductor layer 210, a first gate electrode 230, a first source electrode 250, and a first drain electrode 270. The second TFT 300 may include a second semiconductor layer 310, a second gate electrode 330, a second source electrode 350, and a second drain electrode 370.

For convenience of description, only two of various TFTs are illustrated, and other TFTs may be included in the display apparatus 100. Also, for convenience of description, the display apparatus is described as a top gate structure where a gate electrode configuring a TFT is disposed on a semiconductor layer, but aspects of the present disclosure are not limited thereto. In other aspects, the display apparatus may use a different structure such as a bottom gate structure where a gate electrode is disposed under a semiconductor layer or a double gate structure where a gate electrode is disposed on and under a semiconductor layer.

A first semiconductor layer 210 of the first TFT 200 and a second semiconductor layer 310 of the second TFT 300 may be disposed on the first buffer layer 120.

The first semiconductor layer 210 and the second semiconductor layer 310 may include a polycrystalline semiconductor. For example, the polycrystalline semiconductor may include low temperature polysilicon (LTPS) having high mobility, but aspects of the present disclosure are not limited thereto. When the first semiconductor layer 210 and the second semiconductor layer 310 include a polycrystalline semiconductor, the first semiconductor layer 210 and the second semiconductor layer 310 may have low energy power consumption and have good reliability.

Moreover, each of the first semiconductor layer 210 and the second semiconductor layer 310 may include an oxide semiconductor. For example, each of the first semiconductor layer 210 and the second semiconductor layer 310 may include one of indium-gallium-zinc-oxide (IGZO), indium-zinc-oxide (IZO), indium-gallium-tin-oxide (IGTO), and indium-gallium-oxide (IGO), but aspects of the present disclosure are not limited thereto. When each of the first semiconductor layer 210 and the second semiconductor layer 310 includes an oxide semiconductor, the configuration reduces a leakage current, and thus, a luminance change of a subpixel may be minimized in low speed driving.

When each of the first semiconductor layer 210 and the second semiconductor layer 310 includes a polycrystalline semiconductor or an oxide semiconductor, a partial region of each of the first semiconductor layer 210 and the second semiconductor layer 310 may include an electricity conduction region.

Each of the first semiconductor layer 210 and the second semiconductor layer 310 may include amorphous silicon (a-Si) and may include various organic semiconductor materials such as pentacene, but aspects of the present disclosure are not limited thereto.

The first TFT 200 of the display apparatus according to an aspect of the present disclosure may be the third switching TFT T3. When the first TFT 200 is configured as the third TFT T3, the first semiconductor layer 210 may include an oxide semiconductor.

An oxide semiconductor may prevent a leakage current, and decrease smears at a low gray level, but may need to increase mobility. Increasing the content or a ratio of indium (In) or tin (Sn) included in the oxide semiconductor may increase the mobility, but this also causes the oxide semiconductor to be vulnerable to light. Furthermore, when the third switching TFT T3 is configured as an oxide semiconductor layer, luminance sensitivity may increase based on a variation of a threshold voltage Vth, and due to this, the problem may become more progressively severe. In an aspect of the present disclosure, a planarization layer including a groove and a bank disposed in the groove may be provided for preventing a degradation in a TFT (for example, the third switching TFT T3) caused by external light, internal reflected light, or scattered light. The planarization layer considerably reduces the degradation of the third switching TFT T3 caused by light and prevents decreases in the luminance of a display apparatus.

At least one of elements configuring the first TFT 200 may at least partially overlap the bank 520. The bank 520 may include a black material. Particularly, scattered light where light scattered at a lateral surface of a first electrode 510 is incident on a TFT through the planarization layer may be blocked and may be incident on the TFT to degrade the TFT, causing a reduction in luminance of a display apparatus. However, according to an aspect of the present disclosure, in addition to scattered light, external light, internal reflected light, or scattered light incident on a TFT may be more effectively prevented through the bank 520 filled in the groove disposed in the planarization layer 170. For example, the first bank 521 disposed in the groove of the planarization layer may prevent light scattered at a lateral surface of the first electrode 510 from being incident on the TFT, and preventing reduction of luminance of a display apparatus.

A first insulation layer 130 may be disposed in an entire region of the substrate 110 on the first semiconductor layer 210 and the second semiconductor layer 310.

The first insulation layer 130 may be disposed between the first semiconductor layer 210 and the first gate electrode 230 and may insulate the first semiconductor layer 210 from the first gate electrode 230. The first insulation layer 130 may be disposed between the second semiconductor layer 310 and the second gate electrode 330 and may insulate the second semiconductor layer 310 from the second gate electrode 330.

The first insulation layer 130 may include an insulating material such as nitride silicon (SiNx) or oxide silicon (SiOx), and moreover, may include an insulating organic material, but aspects of the present disclosure are not limited thereto.

The first insulation layer 130 may include a hole for electrically connecting each of the first source electrode 250 and the first drain electrode 270 with the first semiconductor layer 210. The first insulation layer 130 may include a hole for electrically connecting each of the second source electrode 350 and the second drain electrode 370 with the second semiconductor layer 310.

The first gate electrode 230 of the first TFT 200 and the second gate electrode 330 of the second TFT 300 may be disposed on the first insulation layer 130. The first gate electrode 230 may be disposed to overlap the first semiconductor layer 210. The second gate electrode 330 may be disposed to overlap the second semiconductor layer 310.

A storage capacitor 400 may be disposed on the first insulation layer 130. The storage capacitor 400 may include a first capacitor electrode 410 and a second capacitor electrode 420. The storage capacitor 400 may store a data voltage applied through a data line during a certain period, and then, may provide the data voltage to the first electrode 510 (e.g., the anode).

The first capacitor electrode 410 of the storage capacitor 400 may be disposed on the first insulation layer 130.

The first gate electrode 230, the second gate electrode 330, and the first capacitor electrode 410 may be disposed on the same layer. For example, the first gate electrode 230, the second gate electrode 330, and the first capacitor electrode 410 may be disposed on the first insulation layer 130.

The first gate electrode 230, the second gate electrode 330, and the first capacitor electrode 410 may be formed by the same process.

The first gate electrode 230, the second gate electrode 330, and the first capacitor electrode 410 may be formed of a single layer or a multiplayer including one of molybdenum (Mo), copper (Cu), titanium (Ti), aluminum (Al), chrome (Cr), gold (Au), nickel (Ni), neodymium (Nd), tungsten (W), and transparent conductive oxide (TCO), or an alloy thereof, but aspects of the present disclosure are not limited thereto.

A second insulation layer 140 may be disposed in an entire region of the substrate 110 on the first gate electrode 230, the second gate electrode 330, and the first capacitor electrode 410.

The second insulation layer 140 may be disposed between the first gate electrode 230, the first source electrode 250, and the first drain electrode 270 and may insulate the first gate electrode 230, the first source electrode 250, and the first drain electrode 270 from one another. The second insulation layer 140 may be disposed between the second gate electrode 330, the second source electrode 350, and the second drain electrode 370 and may insulate the second gate electrode 330, the second source electrode 350, and the second drain electrode 370 from one another.

The second insulation layer 140 may include a hole for electrically connecting each of the first source electrode 250 and the first drain electrode 270 with the first semiconductor layer 210. The second insulation layer 140 may include a hole for electrically connecting each of the second source electrode 350 and the second drain electrode 370 with the second semiconductor layer 310.

The second insulation layer 140 may include an insulating inorganic material such as SiNx or SiOx, and moreover, may include an insulating organic material, but aspects of the present disclosure are not limited thereto.

The second capacitor electrode 420 of the storage capacitor 400 may be disposed on the second insulation layer 140. The second capacitor electrode 420 may be disposed to overlap the first capacitor electrode 410.

The second capacitor electrode 420 may be formed of a single layer or a multiplayer including one of Mo, Cu, Ti, Al, Cr, Au, Ni, Nd, W, and TCO, or an alloy thereof, but aspects of the present disclosure are not limited thereto.

A third insulation layer 150 may be disposed in over an entire region of the substrate 110 on the second capacitor electrode 420.

The third insulation layer 150 may be disposed between the first gate electrode 230, the first source electrode 250, and the first drain electrode 270 and may insulate the first gate electrode 230, the first source electrode 250, and the first drain electrode 270 from one another. The third insulation layer 150 may be disposed between the second gate electrode 330, the second source electrode 350, and the second drain electrode 370 and may insulate the second gate electrode 330, the second source electrode 350, and the second drain electrode 370 from one another.

The third insulation layer 150 may include a hole for electrically connecting each of the first source electrode 250 and the first drain electrode 270 with the first semiconductor layer 210. The third insulation layer 150 may include a hole for electrically connecting each of the second source electrode 350 and the second drain electrode 370 with the second semiconductor layer 310.

The third insulation layer 150 may include an insulating inorganic material such as SiNx or SiOx, and moreover, may include an insulating organic material, but aspects of the present disclosure are not limited thereto.

The first source electrode 250 and the first drain electrode 270 may be disposed on the third insulation layer 150. The second source electrode 350 and the second drain electrode 370 may be disposed on the third insulation layer 150.

Each of the first source electrode 250 and the first drain electrode 270 may be electrically connected with the first semiconductor layer 210 through the hole of each of the first insulation layer 130, the second insulation layer 140, and the third insulation layer 150. Each of the second source electrode 350 and the second drain electrode 370 may be electrically connected with the second semiconductor layer 310 through the hole of each of the first insulation layer 130, the second insulation layer 140, and the third insulation layer 150.

The first source electrode 250, the first drain electrode 270, the second source electrode 350, and the second drain electrode 370 may be formed of a single layer or a multiplayer including one of Mo, Cu, Ti, Al, Cr, Au, Ni, Nd, W, and TCO, or an alloy thereof, but aspects of the present disclosure are not limited thereto. For example, the first source electrode 250, the first drain electrode 270, the second source electrode 350, and the second drain electrode 370 may be formed in a three-layer structure of Ti/Al/Ti including a conductive metal material, but aspects of the present disclosure are not limited thereto.

A protection layer 160 may be disposed in the entire region of the substrate 110 on the first source electrode 250, the first drain electrode 270, the second source electrode 350, and the second drain electrode 370.

The protection layer 160 may protect the first TFT 200 and the second TFT 300. The protection layer 160 may include an insulating inorganic material such as SiNx or SiOx, and moreover, may include an insulating organic material, but aspects of the present disclosure are not limited thereto.

The protection layer 160 may include a hole for electrically connecting the second TFT 300 with a connection electrode 180 or the first electrode 510. The protection layer 160 may be omitted based on a structure and a type of a TFT.

A planarization layer 170 may be disposed on the protection layer 160. For example, the planarization layer 170 may be an insulation layer or a second protection layer, but aspects of the present disclosure are not limited thereto. The planarization layer 170 may protect a TFT disposed under the planarization layer 170 and may decrease or planarize a step height caused by various patterns. For example, the planarization layer 170 may insulate elements disposed on and under the planarization layer 170. For example, the planarization layer 170 may be disposed as a single layer, but is not limited thereto and may be disposed as two or more layers, based on the arrangement of electrodes.

Because the number of various signal lines increases as the display apparatus 100 advances to a high resolution, it may be difficult to arrange all lines in one layer while securing a minimum interval therebetween. In some cases, an additional layer may be provided. Based on the additional layer, a margin for line arrangement may be increased, and thus, line/electrode arrangement design may be easier. In a case where a dielectric material is used as a planarization layer configured as a multilayer, the planarization layer 170 may be used for forming a capacitance between metal layers.

In a case where the planarization layer 170 is disposed as two layers, the planarization layer 170 may include a first planarization layer 171 and a second planarization layer 172. For example, the first planarization layer 171 may be a fifth insulation layer or a second protection layer, but aspects of the present disclosure are not limited thereto. For example, the second planarization layer 172 may be a sixth insulation layer or a third protection layer, but aspects of the present disclosure are not limited thereto. For example, a hole may be formed in the first planarization layer 171, and a connection electrode 180 may be disposed in the hole. The second planarization layer 172 including a hole may be disposed on the first planarization layer 171 and the connection electrode 180. The first electrode 510 may be disposed in the hole of the second planarization layer 172. Accordingly, the second TFT 300 may be electrically connected with the first electrode 510 through the connection electrode 180.

One end (or a portion or one side) of the connection electrode 180 may be connected with the second TFT 300, and the other end (or another portion or the other side) of the connection electrode 180 may be connected with the first electrode 510.

The connection electrode 180 may be further disposed on the first planarization layer 171.

The connection electrode 180 may be formed of a single layer or a multiplayer including one of Mo, Cu, Ti, Al, Cr, Au, Ni, Nd, W, and TCO, or an alloy thereof, but aspects of the present disclosure are not limited thereto. For example, the connection electrode 180 may be formed in a three-layer structure of Ti/Al/Ti including a conductive material, but aspects of the present disclosure are not limited thereto.

The connection electrode 180 may be omitted, based on a structure and a type of a display apparatus.

The second planarization layer 172 may be disposed on the first planarization layer 171 and the connection electrode 180.

The first planarization layer 171 and the second planarization layer 172 may include one or more of organic insulating materials such as benzocyclobutene (BCB), acryl resin, epoxy resin, phenolic resin, polyamide resin, and polyimide resin, but aspects of the present disclosure are not limited thereto.

The planarization layer 170 of the display apparatus 100 may be disposed as three layers, based on the arrangement of electrodes, but aspects of the present disclosure are not limited thereto. Accordingly, a connection electrode may be further disposed.

The planarization layer 170 according to an aspect of the present disclosure may further include a groove G.

A detailed configuration of each of the planarization layer 170 and the groove G will be described below in detail with reference to FIG. 6.

The groove G may be formed in the planarization layer 170 and the bank 520 or the first bank 521 may be disposed within the groove G to prevent light scattered in a lateral surface of the first electrode 510 being incident on a TFT, and prevent luminance reduction of a display apparatus.

A light emitting device layer 500 may be disposed on the planarization layer 170. The light emitting device layer 500 may include a first electrode 510, an organic layer 540, and a second electrode 550.

The first electrode 510 may be disposed on the planarization layer 170. The first electrode 510 may supply a hole to the organic layer 540 and may include a conductive material having a high work function. The first electrode may be an anode electrode, but aspects of the present disclosure are not limited thereto.

When the display apparatus 100 is a top emission type, the first electrode 510 may be a reflection electrode that reflects light and may include an opaque conductive material. The first electrode 510 may include one or more of silver (Ag), Al, Au, Mo, W, Cr, or an alloy thereof, but aspects of the present disclosure are not limited thereto. For example, the first electrode 510 may be formed in a three-layer structure of Ag/Pd/Cu, but aspects of the present disclosure are not limited thereto. Alternatively, the first electrode 510 may further include a transparent conductive material having a high work function like indium-tin-oxide (ITO).

When the display apparatus 100 is a bottom emission type, the first electrode 510 may include a transparent conductive material which transmits light. For example, the first electrode 510 may include one or more indium tin oxide (ITO) and indium zinc oxide (IZO), but aspects of the present disclosure are not limited thereto.

A portion of the first electrode 510 may protrude from the groove G of the planarization layer 170. For example, an end point (or end or one side) of the first electrode 510 may be disposed between the first bank 521 and the second bank 522, and the first bank 521 and the second bank 522 may prevent external light, internally reflected light, and/or scattered light scattered in a lateral surface of the first electrode 510 from being incident on a TFT, thereby minimizing luminance reduction of a display apparatus.

The bank 520 may be disposed on the first electrode 510 and the planarization layer 170.

The bank 520 may divide a plurality of subpixels SP, minimize the spread of light, and prevent the color mixing occurring in various viewing angles. The bank 520 may define (or differentiate) an emission portion emitting light and a non-emission portion which does not emit light, and the bank 520 may be disposed in the non-emission portion. The bank 520 may include a bank hole which exposes the emission portion and the first electrode 510.

The bank 520 may include one or more of inorganic insulating materials such as SiNx and SiOx, organic insulating materials such as BCB, acryl resin, epoxy resin, phenolic resin, polyamide resin, and polyimide resin, and a photosensitizer including a black pigment, but aspects of the present disclosure are not limited thereto.

The bank 520 may be formed to be black or another color. For example, when the bank 520 includes a black material, the bank 520 may prevent external light, internal reflected light, and/or scattered light scattered in the lateral surface of the first electrode 510 from being incident on a TFT, thereby minimizing luminance reduction of a display apparatus. The bank 520 may be disposed to cover an end (or a partial region) of the first electrode 510.

The bank 520 may include the first bank 521 filled in the groove G of the planarization layer 170 and the second bank 522 disposed on a partial region of the first bank 521 and/or the first electrode 510.

An end point (or end or partial region) of the first electrode 510 may be disposed between the first bank 521 and the second bank 522 and may prevent external light, internal reflected light, and/or scattered light scattered in the lateral surface of the first electrode 510 from being incident on a TFT, thereby minimizing luminance reduction of a display apparatus.

A detailed configuration of the bank 520 will be described below in detail with reference to FIG. 6.

At least one spacer 530 may be disposed on the bank 520.

The spacer 530 may prevent the organic layer 540 from being damaged in performing a process of the organic layer 540 and may minimize the damage of the display apparatus 100 caused by an external impact.

The spacer 530 may include the same material as that of the bank 520 and may be formed simultaneously with the bank 520, or may be formed by a separate process. For example, the spacer 530 may be formed to be transparent, or may be formed to be in black or color. Alternatively, the spacer 530 may include a transparent material, a black material, or a colored material.

A thickness of the spacer 530 may be greater or less than that of the bank 520, and for example, may be 1 μm to 2 μm, but aspects of the present disclosure are not limited thereto.

The spacer 530 may be disposed on the bank 520. For example, the spacer 530 may be disposed on the first bank 521 and the second bank 522.

The spacer 530 may overlap the groove G of the planarization layer 170.

The organic layer 540 may be disposed on the first electrode 510 and the bank 520. The organic layer 540 may include an emission layer (EML) for emitting light of a specific color in each of the plurality of subpixels SP. The emission layer may be a layer which emits light. For example, a hole generated in the first electrode 510 and an electron generated in the second electrode 550 may be injected into the emission layer. The hole and the electron injected into the emission layer may be combined to generate an exciton. When the generated exciton is shifted from an excited state to a ground state, light may be emitted.

For example, the emission layer may include a red emission layer emitting red light, a green emission layer emitting green light, a blue emission layer emitting blue light, and a white emission layer emitting white light. When the organic layer 540 includes the white emission layer, a color filter for converting white light, emitted from the white emission layer, into light of a different color may be disposed on the organic layer 540. Also, the organic layer 540 may further include a hole injection layer (HIL), a hole transport layer (HTL), an electron blocking layer (EBL), a hole blocking layer (HBL), an electron transport layer (ETL), and an electron injection layer (EIL), but aspects of the present disclosure are not limited thereto.

The emission layer of the organic layer 540 may be disposed in each of the plurality of subpixels SP, and the hole injection layer (HIL), the hole transport layer (HTL), the electron blocking layer (EBL), the hole blocking layer (HBL), the electron transport layer (ETL), and the electron injection layer (EIL) of the organic layer 540 may be entirely disposed in the display area AA.

The organic layer 540 of the display apparatus according to the present disclosure may be an emission unit. The emission unit may be provided as one or more. For example, a plurality of emission units may be stacked between the first electrode 510 and the second electrode 550 to configure a stack structure. In this case, a charge generating layer may be further disposed between the plurality of emission units. The emission unit may be provided in plurality for each subpixel SP.

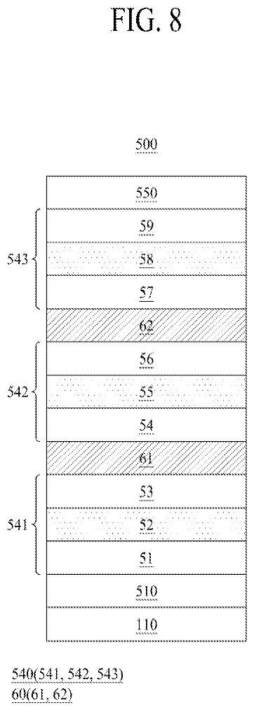

The emission unit will be described below in detail with reference to FIG. 8.

The second electrode 550 may be disposed on the organic layer 540. The second electrode 550 may supply an electron to the organic layer 540 and may include a conductive material having a low work function. The second electrode may be a cathode electrode, but aspects of the present disclosure are not limited thereto.

When the display apparatus 100 is the top emission type, the second electrode 550 may be disposed by using a transparent conductive material which transmits light. For example, the second electrode 550 may include one or more of ITO and IZO, but aspects of the present disclosure are not limited thereto. Also, the second electrode 550 may be disposed by using a semitransparent conductive material which transmits light. For example, the second electrode 550 may include one or more of alloys such as LiF/Al, CsF/Al, Mg:Ag, Ca/Ag, Ca:Ag, LiF/Mg:Ag, LiF/Ca/Ag, and LiF/Ca:Ag, but aspects of the present disclosure are not limited thereto. A moisture barrier layer 560 may be additionally formed between the second electrode 550 and the encapsulation layer 600, but aspects of the present disclosure are not limited thereto.

When the display apparatus 100 is the bottom emission type, the second electrode 550 may be a reflection electrode which reflects light and may be disposed by using an opaque conductive material. For example, the second electrode 550 may include one or more of Ag, Al, Au, Mo, W, Cr, or an alloy thereof, but aspects of the present disclosure are not limited thereto.

An encapsulation layer 600 may be disposed on the second electrode 550. The encapsulation layer 600 may protect the organic layer 540 from external water, oxygen, or particles. For example, the encapsulation layer 600 may prevent the penetration of oxygen and water from the outside to prevent the oxidation of a light emitting material and an electrode material.

The encapsulation layer 600 may include a transparent material so that light emitted from the emission layer passes through the encapsulation layer 600.

The encapsulation layer 600 may include a first encapsulation layer 610, a second encapsulation layer 620, and a third encapsulation layer 630, which prevents the penetration of water or oxygen. The encapsulation layer 600 may have a structure where the first encapsulation layer 610, the second encapsulation layer 620, and the third encapsulation layer 630 are alternately stacked, but aspects of the present disclosure are not limited thereto.

The first encapsulation layer 610 and the third encapsulation layer 630 may include one or more inorganic materials of SiNx, SiOx, and oxide aluminum (AlyOz), but aspects of the present disclosure are not limited thereto. The first encapsulation layer 610 and the third encapsulation layer 630 may be formed by a vacuum film formation process such as a chemical vapor deposition (CVD) process or an atomic layer deposition (ALD) process, but aspects of the present disclosure are not limited thereto.

Each of the first encapsulation layer 610 and the third encapsulation layer 630 may be formed of two or more layers. For example, the first encapsulation layer 610 may be formed in a three-layer structure of SiOx/SiNx/SiOx, but aspects of the present disclosure are not limited thereto. Alternatively, the first encapsulation layer 610 may be formed in a four-layer structure of SiOx/SiNx/SiOx/SiOx, but aspects of the present disclosure are not limited thereto.

The second encapsulation layer 620 may cover foreign materials or particles occurring in a manufacturing process. Also, the second encapsulation layer 620 may planarize a surface of the first encapsulation layer 610. For example, the second encapsulation layer 620 may be referred to as a particle cover layer, but the terms are not limited thereto.

The second encapsulation layer 620 may include an organic material (for example, silicon oxycarbon (SiOCz), epoxy, polyimide, polyethylene, or acrylate-based polymer), but aspects of the present disclosure are not limited thereto.

The second encapsulation layer 620 may include a thermo-curable material or a photo-curable material, which is cured by heat or light.

A touch sensor layer 700 may be disposed on the encapsulation layer 600.

The touch sensor layer 700 may include a first touch electrode 740_R, a first touch connection electrode 720, a second touch electrode, and a second touch connection electrode 740_C.

A portion of each of the first touch electrode 740_R, the first touch connection electrode 720, the second touch electrode, and the second touch connection electrode 740_C may be disposed to overlap the bank 520.

The first touch electrode 740_R, the second touch electrode, the first touch connection electrode 720, and the second touch connection electrode 740_C may be formed with a mesh pattern where metal lines having a small line width intersect with each other. The mesh pattern may have a quadrilateral shape. Also, a shape of the mesh pattern may be a tetragonal shape, a pentagonal shape, a hexagonal shape, a circular shape, or an oval shape, but aspects of the present disclosure are not limited thereto.

The first touch electrode 740_R, the second touch electrode, the first touch connection electrode 720, and the second touch connection electrode 740_C may be disposed by using an opaque conductive material having a low resistance. For example, each of the first touch electrode 740_R, the second touch electrode, the first touch connection electrode 720, and the second touch connection electrode 740_C may be formed of a single layer or a multiplayer including one of Mo, Cu, Ti, Al, Cr, Au, Ni, Nd, W, and TCO, or an alloy thereof, but aspects of the present disclosure are not limited thereto. For example, each of the first touch electrode 740_R, the second touch electrode, the first touch connection electrode 720, and the second touch connection electrode 740_C may be formed in a three-layer structure of Ti/Al/Ti including a conductive metal material, but aspects of the present disclosure are not limited thereto.

Each of the first touch electrode 740_R, the second touch electrode, the first touch connection electrode 720, and the second touch connection electrode 740_C may include the same material as that of each of the first source electrode 250, the first drain electrode 270, the second source electrode 350, and the second drain electrode 370, but aspects of the present disclosure are not limited thereto.

A buffer layer 710 may be disposed on the encapsulation layer 600. The buffer layer 710 may prevent external water or a chemical solution (for example, a developer or an etchant) used in a manufacturing process from penetrating into the light emitting device layer 500. Also, a problem may be solved where a plurality of touch sensor metals disposed on the buffer layer 710 are disconnected by an external impact, and an interference signal may be blocked when driving of the touch sensor layer 700. For example, the buffer layer 710 may be a touch buffer layer or a second buffer layer, but aspects of the present disclosure are not limited thereto.

The buffer layer 710 may include one or more of inorganic insulating materials, such as SiNx and SiOx, and organic insulating materials such as BCB, acryl resin, epoxy resin, phenolic resin, polyamide resin, and polyimide resin, but aspects of the present disclosure are not limited thereto.

The first touch connection electrode 720 may be disposed on the buffer layer 710.

For example, the first touch connection electrode 720 may be disposed between first touch electrodes 740_R that are adjacent to each other in a first direction (or an X-axis direction). The first touch connection electrode 720 may electrically connect, with each other, a plurality of first touch electrodes 740_R which are separated from and adjacent to each other in the first direction (or the X-axis direction), but aspects of the present disclosure are not limited thereto.

The first touch connection electrodes 720 may be disposed to overlap the second touch connection electrode 740_C which connects, with each other, second touch electrodes adjacent to each other in a second direction (or a Y-axis direction). The first touch connection electrode 720 and the second touch connection electrode 740_C may be formed on different layers, and thus, may be electrically insulated from each other. For example, the first touch connection electrode 720 may be a first connection electrode, but aspects of the present disclosure are not limited thereto. For example, the second touch connection electrode 740_C may be a second connection electrode, but aspects of the present disclosure are not limited thereto.

An insulation layer 730 may be disposed on the buffer layer 710 and the first touch connection electrode 720. For example, the insulation layer 730 may be a touch insulation layer or a fourth insulation layer, but aspects of the present disclosure are not limited thereto.

The insulation layer 730 may include a hole for electrically connecting the first touch electrode 740_R with the first touch connection electrode 720. For example, the insulation layer 730 may electrically insulate the second touch electrode from the second touch connection electrode 740_C. For example, the insulation layer 730 may be formed of a single layer of SiNx or SiOx or a multilayer thereof, but aspects of the present disclosure are not limited thereto.

The first touch electrode 740_R, the second touch electrode, and the second touch connection electrode 740_C may be disposed on the insulation layer 730.

The first touch electrode 740_R and the second touch electrode may be separated from each other by a certain interval. At least one first touch electrodes 740_R adjacent to each other in the first direction (or the X-axis direction) may be formed separated from each other. At least one first touch electrodes 740_R adjacent to each other in the first direction (or the X-axis direction) may be connected with the first touch connection electrode 720 disposed between a plurality of first touch electrodes 740_R. For example, a plurality of first touch electrodes 740_R adjacent to each other may be connected with the first touch connection electrode 720 through the hole of the insulation layer 730.

The second touch electrodes that are adjacent to each other in the second direction (or the Y-axis direction) may be connected with each other by the second touch connection electrode 740_C. The second touch electrode and the second touch connection electrode 740_C may be formed on the same layer. For example, the second touch connection electrode 740_C may be disposed between a plurality of second touch electrodes on the same layer as the second touch electrode. The second touch connection electrode 740_C may be formed to extend from the second touch electrode.

The first touch electrode 740_R, the second touch electrode, and the second touch connection electrode 740_C may be formed by the same process.

The planarization layer 750 may be disposed on the first touch electrode 740_R, the second touch electrode, and the second touch connection electrode 740_C. For example, the planarization layer 750 may be a touch planarization layer, an insulation layer, or a protection layer, but aspects of the present disclosure are not limited thereto.

A touch driving circuit may receive a touch sensing signal from the first touch electrode 740_R. Also, the touch driving circuit may transfer a touch driving signal from the second touch electrode. The touch driving circuit may sense a user touch by using a mutual capacitance between a plurality of first touch electrodes 740_R and the second touch electrode. For example, when a touch operation is performed in the display apparatus 100, a capacitance variation may occur between the first touch electrode 740_R and the second touch electrode. The touch driving circuit may sense the capacitance variation to detect touch coordinates.

A dummy portion may be further disposed in a portion of a non-display area NA of the touch sensor layer 700. The dummy portion may be disposed between a touch line and an end point (or end) of the substrate 110. For example, the dummy portion may be a touch dummy or touch dummy portion, but aspects of the present disclosure are not limited thereto.

The dummy portion may be insulated from the touch line and a touch block, and a constant voltage may be applied thereto. The dummy portion may distribute noise caused by a parasitic capacitance formed by a signal line of a gate driver to decrease noise caused by the signal line.

Hereinafter, a planarization layer and a bank according to the present disclosure will be described with reference to FIG. 6.

FIG. 6 is a cross-sectional view taken along line II-II′ of FIG. 4 according to an aspect of the present disclosure.

FIG. 6 is an enlarged cross-sectional view of adjacent emission portions and a bank and a planarization layer disposed between the adjacent emission portions, according to an aspect of the present disclosure.

Referring to FIG. 6, a planarization layer 170 may include a groove G. A bank 520 may include a first bank 521 filled in the groove G of the planarization layer 170 and a second bank 522 disposed on the first bank 521.

The groove G of the planarization layer 170 may be disposed in a non-emission portion. The groove G of the planarization layer 170 may be formed by etching a portion of the planarization layer 170. For example, the planarization layer 170 may be etched by adjusting a process condition in forming a first electrode 510. Therefore, the groove G may have an undercut structure at an end point (or end or one side) of the first electrode 510 configured as a metal layer.

The bank 520 may be disposed in the non-emission portion and may be disposed in a partial region of the first electrode 510 and in the groove G.

The first bank 521 may be disposed on the groove G of the planarization layer 170. An end point (or end or one side) of the first bank 521 may partially overlap the end point (or end or one side) of the first electrode 510.

The second bank 522 may be disposed over a partial region on the first electrode 510. An end point (or end or one side) of the second bank 522 may partially overlap the end point (or end or one side) of the first electrode 510.

The bank 520 may be disposed to cover the end of the first electrode 510.

Alternatively, the bank 520 may be further disposed under the first electrode 510. For example, the first bank 521 and the second bank 522 may surround an upper surface, a lower surface, and a lateral surface of a partial region of the first electrode 510. The partial region of the first electrode 510 may protrude from the groove G.

The bank 520 may be formed in black or color. For example, the bank 520 may include a black material or a colored material.

A thickness of the bank 520 may be 1.5 μm to 2.5 μm. When a thickness of the bank 520 may be less than 1.5 μm, it may be difficult to effectively block external light, internal reflected light, or scattered light. On the other hand, when a thickness of the bank 520 is more than 2.5 μm, the film detachment of the bank 520 may occur due to the out-gassing of the bank 520.

The first bank 521 may have a first thickness T1, and the second bank 522 may have a second thickness T2. The first thickness T1 of the first bank 521 may differ from the second thickness T2 of the second bank 522. For example, the first thickness T1 of the first bank 521 may be greater than the second thickness T2 of the second bank 522. For example, the first bank 521 may be 1.0 μm to 1.5 μm, and the second bank 522 may be 0.5 μm to 1 μm. The second thickness T2 of the second bank 522 may be a thickness of the groove G which is formed by etching the planarization layer 170. When a time that the planarization layer 170 is exposed to a chemical solution (for example, a developer or an etchant, an etching gas, or pressure) increases while etching the planarization layer 170 to form the groove G, a problem may occur in a TFT, which is formed before the groove G is formed. Accordingly, the second bank 522 may effectively block external light, internal reflected light, or scattered light and may be set to have a thickness which does not cause a problem of a display apparatus.

Therefore, in a display apparatus according to an aspect of the present disclosure, a bank disposed in a partial region on a first electrode and a groove of a planarization layer may block external light, internal reflected light, or scattered light of a first electrode to considerably decrease a degradation in a TFT (for example, a third switching TFT T3), and thus, may minimize luminance reduction of the display apparatus. Accordingly, a TFT may be normally driven, thereby enhancing a sense of beauty, lifetime, and reliability for users. Also, according to an aspect of the present disclosure, a problem where the luminance of a display apparatus is reduced may be solved, thereby providing a display apparatus has reduced power consumption.

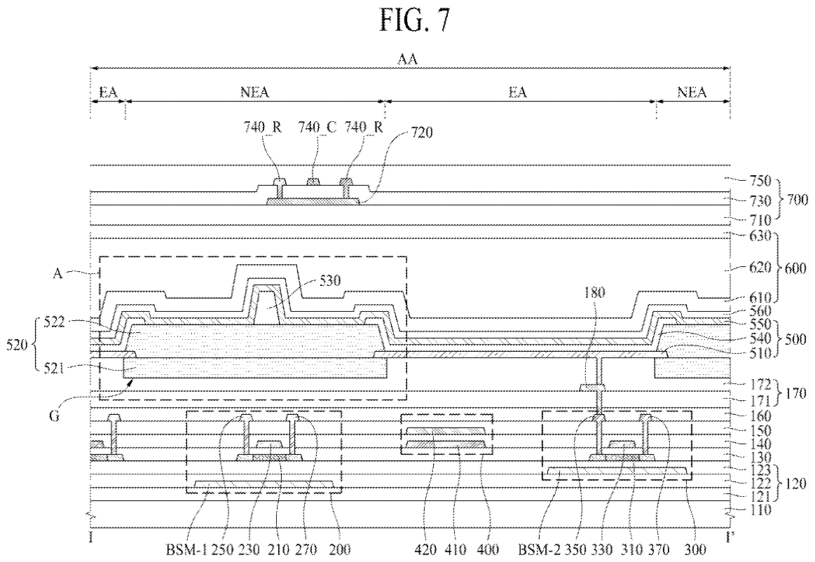

FIG. 7 is a cross-sectional view of a display apparatus 100 according to another aspect of the present disclosure.

Except for a layer where a first blocking layer BSM-1 and a second blocking layer BSM-2 are disposed, the display apparatus 100 of FIG. 7 may be substantially the same as the display apparatus of FIG. 5, and thus, repeated descriptions are omitted.

The display apparatus 100 according to another aspect of the present disclosure may further include the first blocking layer BSM-1 and the second blocking layer BSM-2.

The first blocking layer BSM-1 and the second blocking layer BSM-2 may be respectively disposed under a first TFT 200 and a second TFT 300. For example, the first blocking layer BSM-1 may be disposed under a first semiconductor layer 210 and may be disposed to overlap the first semiconductor layer 210. Also, the second blocking layer BSM-2 may be disposed under a second semiconductor layer 310 and may be disposed to overlap the second semiconductor layer 310.

Each of the first blocking layer BSM-1 and the second blocking layer BSM-2 may have an area which is greater than that of the first semiconductor layer 210 and the second semiconductor layer 310.

A blocking layer may more minimize light incident from the outside of a display apparatus that is irradiated onto a semiconductor layer. As described above, light degrades the semiconductor layer. Also, the blocking layer may prevent an electric charge from flowing in from a substrate. For example, when a voltage is applied to a gate electrode of a TFT for a long time, due to an electric field E occurring in the TFT, an electric charge of the substrate may flow into a channel region of a semiconductor layer of the TFT to change the amount of electric charge of a corresponding channel region. The electric charge may be a hole or an electric charge, based on a polarity of an electric field. The substrate may change a current of the TFT to cause a variation of a threshold voltage Vth of the TFT. This may cause an afterimage and a luminance change of a pixel. Accordingly, the blocking layer may be disposed between the substrate and the semiconductor layer to prevent an undesired electric charge from flowing into the TFT, and thus, prevent a variation of the threshold voltage Vth of the TFT, thereby preventing the occurrence of an afterimage and enhancing display quality.

The first blocking layer BSM-1 and the second blocking layer BSM-2 may be disposed on different layers. A vertical distance between the first semiconductor layer 210 and the first blocking layer BSM-1 may be a first vertical distance. A vertical distance between the second semiconductor layer 310 and the second blocking layer BSM-2 may be a second vertical distance. The first vertical distance may differ from the second vertical distance. For example, the first vertical distance between the first semiconductor layer 210 of the first TFT 200 and the first blocking layer BSM-1 may be greater than the vertical distance between the second semiconductor layer 310 of the second TFT 300 and the second blocking layer BSM-2.

Features desired by TFTs may differ. For example, when the first TFT 200 is a switching TFT, the switching TFT may need a fast operation where the switching TFT is turned on or off with a voltage, and when the second TFT 300 is a driving TFT including an oxide semiconductor layer, a defect may occur in a low grayscale region requiring precise current control because a current variation value corresponding to a unit voltage variation value is large in terms of a material characteristic of an oxide semiconductor. Accordingly, a driving TFT is needed where a variation value of a current in a semiconductor layer is relatively insensitive to a variation value of a voltage applied to a gate electrode of the second TFT 300, and a fast turn-on and turn-off function of the first TFT 200 is maintained.

A capacitance may be formed in each of the first TFT 200 and the second TFT 300. For example, a capacitance may be formed between a blocking layer, a gate electrode, and a semiconductor layer of each of the first TFT 200 and the second TFT 300 or in the semiconductor layer.

A capacitor having a first capacitance C1 may be formed between a blocking layer BSM and the semiconductor layer. A capacitor having a second capacitance C2 may be formed between the semiconductor layer and a gate electrode. As an end point (or end) of the semiconductor layer is doped with impurities in the semiconductor layer, a parasitic capacitor having a third capacitance C_{ACT} may be formed in the semiconductor layer.

In the display apparatus according to an aspect of the present disclosure, the amount of variation of an effective gate voltage affecting a driving current applied to the light emitting device layer 500 may be determined based on the following Equation 1.

$$Δ {V}_{eff} = \frac{{C}_{2}}{{C}_{2} + {C}_{ACT} + {C}_{1}} \times Δ {V}_{GAT} \qquad [ Equation 1 ]$$

In Equation, 1, ΔV_{eff} may denote the amount of variation of an effective gate voltage (or effective voltage) and may be a voltage actually applied to a channel of the second semiconductor layer 310. ΔV_{GAT} may denote the amount of variation of a voltage applied to the second gate electrode 330.

Referring to Equation 1, generating of a driving current may be affected by adjusting the first capacitance C1 formed between the second semiconductor layer 310 and the second blocking layer BSM-2. For example, the effective voltage ΔV_{eff} applied to a channel of the second semiconductor layer 310 may be adjusted by an effective voltage applied to an oxide semiconductor pattern on the basis of the adjustment of the first capacitance C1 in an inverse proportion to the first capacitance C1.

$$C = \frac{Q}{y} = \frac{{ε}_{o} A}{d} \qquad [ Equation 2 ]$$

In Equation 2, εₒ may be a dielectric constant, A may denote an area, and d may denote an electrode distance.

Referring to Equation 2, a capacitance may increase as a distance between electrodes is reduced. Accordingly, when a magnitude of the first capacitance C1 increases as the second blocking layer BSM-2 is disposed close to the second semiconductor layer 310, the amount of variation ΔV_{eff} of a voltage applied to the second semiconductor layer 310 may be reduced.

On the other hand, because a distance between the first semiconductor layer 210 of the first TFT 200 and the first blocking layer BSM-1 increases relatively, a capacitance of the first TFT 200 may decrease, and thus, the amount of variation ΔV_{eff} of an effect current value flowing in the second semiconductor layer 310 may be reduced. This may denote that a control range of the second TFT 300 capable of being controlled through the amount of variation ΔV_{gat} of a voltage applied to the second gate electrode 330 increases.

Therefore, a second vertical distance D2 between the second semiconductor layer 310 of the second TFT 300 and the second blocking layer BSM-2 may be set to be less than a first vertical distance D1 between the first semiconductor layer 210 of the first TFT 200 and the first blocking layer BSM-1, and thus, a range for controlling a gray level by using the second TFT 300 may increase. As a result, a light emitting device layer may be precisely controlled at a low gray level, and thus, prevent screen smears occurring at a low gray level. At least one insulation layer and buffer layer may be disposed between the first blocking layer BSM-1 and the second blocking layer BSM-2. Also, the first blocking layer BSM-1 may be disposed more downward than the second blocking layer BSM-2.

The buffer layer 120 may include a first buffer layer 121, a second buffer layer 122, and a third buffer layer 123. The first buffer layer 121, the second buffer layer 122, and the third buffer layer 123 may be sequentially arranged. The number of buffer layers 120 is not limited thereto.

The first blocking layer BSM-1 may be disposed on the first buffer layer 121. The second buffer layer 122 may be disposed on the first buffer layer 121 and the first blocking layer BSM-1. The second blocking layer BSM-2 may be disposed on the second buffer layer 122. Also, the third buffer layer 123 may be disposed on the second buffer layer 122 and the second blocking layer BSM-2.

The second vertical distance D2 between the second semiconductor layer 310 of the second TFT 300 and the second blocking layer BSM-2 may be set to be less than the first vertical distance D1 between the first semiconductor layer 210 of the first TFT 200 and the first blocking layer BSM-1. This may enable an increase in a range for controlling a gray level by using the second TFT 300. Accordingly, a light emitting device layer may be precisely controlled at a low gray level, and thus, prevent screen smears at a low gray level.

FIG. 8 is a cross-sectional view of an emission unit according to an aspect of the present disclosure. The emission unit illustrated in FIG. 8 may be identically applied to FIGS. 4 and 5.

A stack structure may be configured by stacking a plurality of emission units 540 between a first electrode 510 and a second electrode 550. In FIG. 8, three emission units are illustrated, but two or three or more emission units may be configured. However, aspects of the present disclosure are not limited thereto.

Referring to FIG. 8, the emission unit 540 may include a first emission unit 541, a second emission unit 542, and a third emission unit 543, and a charge generating layer (CGL) 60 may be further disposed between the plurality of emission units 540. For example, a first charge generating layer 61 may be disposed between the first emission unit 541 and the second emission unit 542, and a second charge generating layer 62 may be disposed between the second emission unit 542 and the third emission unit 543.

A light emitting device layer configured with a plurality of emission units may increase more in emission efficiency and lifetime than a light emitting device layer configured with one organic layer or one emission unit. For example, because a plurality of emission units are serially connected with one another for satisfying a desired condition of emission intensity or the amount of emitted light in a display apparatus, a stress of an organic layer or a single emission unit, the concentration of a current based on a resistance, and a degradation may be dispersed, and thus, the efficiency and lifetime of each emission unit may increase, thereby enhancing the reliability of a display apparatus.

The charge generating layer (CGL) 60 may be disposed between the plurality of emission units to adjust a charge balance. The charge generating layer 60 may include an N-type charge generating layer (N-CGL) and a P-type charge generating layer (P-CGL). The N-type charge generating layer (N-CGL) may inject an electron into an emission unit and may be configured as an organic layer which is formed by doping a host with alkali metal such as lithium (Li), sodium (Na), potassium (K), or cesium (Cs) or alkali earth metal such as magnesium (Mg), strontium (Sr), barium (Ba), or radium (Ra), but aspects of the present disclosure are not limited thereto. The P-type charge generating layer (P-CGL) may inject a hole into an emission unit and may be configured as an organic layer including a P-type dopant, but aspects of the present disclosure are not limited thereto.

The first emission unit 541 may be disposed on the first electrode 510. The first emission unit 541 may include a first hole transport layer (HTL) 51, a first emission layer (EML) 52, and a first electron transport layer (ETL) 53. The first emission unit 541 may further include a hole injection layer (HIL) and/or an electron blocking layer (EBL), and the hole injection layer (HIL) and/or the electron blocking layer (EBL) may be disposed between the first electrode 510 and the first hole transport layer (HTL) 51.

The hole injection layer (HIL) may be disposed on the first electrode 510. The hole injection layer (HIL) may smoothly inject a hole from the first electrode 510 into the first hole transport layer (HTL) 51.

The first hole transport layer (HTL) 51 may be disposed on the first electrode 510 or the hole injection layer (HIL). The first hole transport layer (HTL) 51 may supply the first emission layer (EML) 52 with a hole from the first electrode 510 or the hole injection layer (HIL). The first hole transport layer (HTL) 51 may be configured by applying two or more layers or two or more materials.

The first emission layer (EML) 52 may be disposed on the first hole transport layer (HTL) 51. Holes supplied through the first hole transport layer (HTL) 51 and electrons supplied through the first electron transport layer (ETL) 53 may be recombined in the first emission layer (EML) 52, and thus, light may be emitted.

The first emission layer (EML) 52 may emit light having one of blue, deep blue, or sky blue. An emission region of the first emission layer (EML) 52 may be a range of 440 nm to 480 nm.

The first emission layer (EML) 52 may further include a first auxiliary emission layer on or under the first emission layer (EML) 52. The first auxiliary emission layer may include a single layer emitting blue light, yellow-green light, or red light, or a plurality of layers configured by a combination thereof.

The first emission layer (EML) 52 may include at least one host and dopant. Alternatively, the first emission layer (EML) 52 may be configured with at least one dopant and a mixed host where two or more hosts are mixed. The mixed host may include a host having a hole transport characteristic and a host having an electron transport characteristic. When an emission layer is configured with the mixed host, a charge balance of the emission layer may be adjusted, and thus, the efficiency of the emission layer may be enhanced. The dopant may include a fluorescent dopant or a phosphorescent dopant.

The first electron transport layer (ETL) 53 may be disposed on the first emission layer (EML) 52. The first electron transport layer (ETL) 53 may supply the first emission layer (EML) 52 with an electron from the first charge generating layer 61. Therefore, a hole supplied through the first hole transport layer (HTL) 51 and an electron supplied through the first electron transport layer (ETL) 53 may be recombined in the first emission layer (EML) 52, and thus, light may be emitted.

The first electron transport layer (ETL) 53 may be configured by applying two or more layers or two or more materials. An electron injection layer (EIL) may be further provided on the first electron transport layer (ETL) 53.

An electron blocking layer (EBL) and a hole blocking layer (HBL) may be further provided for enhancing the efficiency of the first emission layer (EML) 52. The electron blocking layer (EBL) may be disposed between the first hole transport layer (HTL) 51 and the first emission layer (EML) 52, and the hole blocking layer (HBL) may be disposed between the first electron transport layer (ETL) 53 and the first emission layer (EML) 52.

A first charge generating layer 61 may be disposed on the first emission unit 541. The first charge generating layer 61 may be disposed between the first emission unit 541 and the second emission unit 542.

The first charge generating layer 61 may include an N-type charge generating layer (N-CGL) supplying an electron to the first emission unit 541 and a P-type charge generating layer (P-CGL) supplying a hole to the second emission unit 542. The N-type charge generating layer (N-CGL) may be disposed adjacent to the first emission unit 541, and the P-type charge generating layer (P-CGL) may be disposed adjacent to the second emission unit 542. For example, the N-type charge generating layer (N-CGL) may be disposed on the first emission unit 541, and the P-type charge generating layer (P-CGL) may be disposed on the N-type charge generating layer (N-CGL).

The second emission unit 542 may be disposed on the first charge generating layer 61. The second emission unit 542 may include a second hole transport layer (HTL) 54, a second emission layer (EML) 55, and a second electron transport layer (ETL) 56. The second emission unit 542 may further include a hole injection layer (HIL) and/or an electron blocking layer (EBL), and the hole injection layer (HIL) and/or the electron blocking layer (EBL) may be disposed between the first charge generating layer 61 and the second hole transport layer (HTL) 54.

The second hole transport layer (HTL) 54 may be disposed on the first charge generating layer 61. The second hole transport layer (HTL) 54 may supply the second emission layer (EML) 55 with a hole from the P-type charge generating layer (P-CGL). The second hole transport layer (HTL) 54 may be configured by applying two or more layers or two or more materials.

The second emission layer (EML) 55 may be disposed on the second hole transport layer (HTL) 54. A hole supplied through the second hole transport layer (HTL) 54 and an electron supplied through the second electron transport layer (ETL) 56 may be recombined in the second emission layer (EML) 55, and thus, light may be emitted.

The second emission layer (EML) 55 may emit light having one of blue, deep blue, or sky blue. In this case, an emission region of the second emission layer (EML) 55 may be a range of 440 nm to 480 nm.

The second emission layer (EML) 55 may emit yellow-green light or green light. The second emission layer (EML) 55 may include a plurality of emission layers emitting yellow-green light and red light, a plurality of emission layers emitting yellow light and red light, and a plurality of emission layers emitting green light and red light. In a case where the second emission layer (EML) 55 emits yellow-green light, an emission region of the second emission layer (EML) 55 may be a range of 510 nm to 590 nm. In a case where the second emission layer (EML) 55 emits green light, an emission region of the second emission layer (EML) 55 may be a range of 510 nm to 580 nm. In a case where the second emission layer (EML) 55 is configured with a plurality of emission layers emitting yellow-green light and red light, an emission region of the second emission layer (EML) 55 may be a range of 510 nm to 650 nm. In a case where the second emission layer (EML) 55 is configured with a plurality of emission layers emitting yellow light and red light, an emission region of the second emission layer (EML) 55 may be a range of 540 nm to 650 nm. In a case where the second emission layer (EML) 55 is configured with a plurality of emission layers emitting green light and red light, an emission region of the second emission layer (EML) 55 may be a range of 510 to 650 nm.

The second emission layer (EML) 55 may further include a second auxiliary emission layer on or under the second emission layer (EML) 55. The second auxiliary emission layer may include a single layer emitting blue light, yellow-green light, or red light, or a plurality of layers configured by a combination thereof.

The second emission layer (EML) 55 may include at least one host and dopant. Alternatively, the second emission layer (EML) 55 may be configured with at least one dopant and a mixed host where two or more hosts are mixed. The mixed host may include a host having a hole transport characteristic and a host having an electron transport characteristic. When an emission layer is configured with the mixed host, a charge balance of the emission layer may be adjusted, and thus, the efficiency of the emission layer may be enhanced. The dopant may include a fluorescent dopant or a phosphorescent dopant.

The second electron transport layer (ETL) 56 may be disposed on the second emission layer (EML) 55. The second electron transport layer (ETL) 56 may supply the second emission layer (EML) 55 with an electron from the second charge generating layer 62. Therefore, a hole supplied through the second hole transport layer (HTL) 54 and an electron supplied through the second electron transport layer (ETL) 56 may be recombined in the second emission layer (EML) 55, and thus, light may be emitted.

The second electron transport layer (ETL) 56 may be configured by applying two or more layers or two or more materials. An electron injection layer (EIL) may be further provided on the second electron transport layer (ETL) 56.

An electron blocking layer (EBL) and a hole blocking layer (HBL) may be further provided for enhancing the efficiency of the second emission layer (EML) 55. The electron blocking layer (EBL) may be disposed between the second hole transport layer (HTL) 54 and the second emission layer (EML) 55, and the hole blocking layer (HBL) may be disposed between the second electron transport layer (ETL) 56 and the second emission layer (EML) 55.

A second charge generating layer 62 may be disposed on the second emission unit 542. The second charge generating layer 62 may be disposed between the second emission unit 542 and the third emission unit 543.

The second charge generating layer 62 may include an N-type charge generating layer (N-CGL) supplying an electron to the second emission unit 542 and a P-type charge generating layer (P-CGL) supplying a hole to the third emission unit 543. The N-type charge generating layer (N-CGL) may be disposed adjacent to the second emission unit 542, and the P-type charge generating layer (P-CGL) may be disposed adjacent to the third emission unit 543. For example, the N-type charge generating layer (N-CGL) may be disposed on the second emission unit 542, and the P-type charge generating layer (P-CGL) may be disposed on the N-type charge generating layer (N-CGL).

The third emission unit 543 may be disposed on the second charge generating layer 62. The third emission unit 543 may include a third hole transport layer (HTL) 57, a third emission layer (EML) 58, and a third electron transport layer (ETL) 59. The third emission unit 543 may further include a hole injection layer (HIL) and/or an electron blocking layer (EBL), and the hole injection layer (HIL) and/or the electron blocking layer (EBL) may be disposed between the second charge generating layer 62 and the third hole transport layer (HTL) 57.

The third hole transport layer (HTL) 57 may be disposed on the second charge generating layer 62. The third hole transport layer (HTL) 57 may supply the third emission layer (EML) 58 with a hole from the P-type charge generating layer (P-CGL). The third hole transport layer (HTL) 57 may be configured by applying two or more layers or two or more materials.

The third emission layer (EML) 58 may be disposed on the third hole transport layer (HTL) 57. A hole supplied through the third hole transport layer (HTL) 57 and an electron supplied through the third electron transport layer (ETL) 59 may be recombined in the third emission layer (EML) 58, and thus, light may be emitted (YG).

The third electron transport layer (ETL) 59 may be disposed on the third emission layer (EML) 58. The third electron transport layer (ETL) 59 may supply the third emission layer (EML) 58 with an electron from the second electrode 550. Accordingly, a hole supplied through the third hole transport layer (HTL) 57 and an electron supplied through the third electron transport layer (ETL) 59 may be recombined in the third emission layer (EML) 58, and thus, light may be emitted.

The third emission layer (EML) 58 may emit light having one of blue, deep blue, or sky blue. An emission region of the third emission layer (EML) 58 may be a range of 440 nm to 480 nm.

The third emission layer (EML) 58 may further include a third auxiliary emission layer on or under the third emission layer (EML) 58. The third auxiliary emission layer may include a single layer emitting blue light, yellow-green light, or red light, or a plurality of layers configured by a combination thereof.

The third emission layer (EML) 58 may include at least one host and dopant.

Alternatively, the third emission layer (EML) 58 may be configured with at least one dopant and a mixed host where two or more hosts are mixed. The mixed host may include a host having a hole transport characteristic and a host having an electron transport characteristic. When an emission layer is configured with the mixed host, a charge balance of the emission layer may be adjusted, and thus, the efficiency of the emission layer may be enhanced. The dopant may include a fluorescent dopant or a phosphorescent dopant.

The third electron transport layer (ETL) 59 may be configured by applying two or more layers or two or more materials. An electron injection layer (EIL) may be further provided on the third electron transport layer (ETL) 59.

An electron blocking layer (EBL) and a hole blocking layer (HBL) may be further provided for enhancing the efficiency of the second emission layer (EML) 55. The electron blocking layer (EBL) may be disposed between the third hole transport layer (HTL) 57 and the third emission layer (EML) 58, and the hole blocking layer (HBL) may be disposed between the third electron transport layer (ETL) 59 and the third emission layer (EML) 58.

A display apparatus according to an aspect of the present specification may be described as follows.

A display apparatus according to an aspect of the present specification may comprise a substrate including an emission portion and a non-emission portion adjacent to the emission portion, a planarization layer disposed on the substrate, the planarization layer including a groove disposed in the non-emission portion, a first electrode disposed in the emission portion and the non-emission portion, and a bank disposed in the non-emission portion and provided in a partial region on the first electrode and the groove.

According to the aspect of the present specification, the bank comprises a black material.

According to the aspect of the present specification, the bank is filled in the groove.

According to the aspect of the present specification, the bank is disposed under the first electrode.

According to the aspect of the present specification, a thickness of the bank is 1.5 μm to 2.5 μm.

According to the aspect of the present specification, a partial region of the first electrode protrudes from the groove.

According to the aspect of the present specification, the display apparatus may further comprise a spacer overlapping the groove.

According to the aspect of the present specification, spacer is disposed on the bank.

According to the aspect of the present specification, the display apparatus may further comprise a first thin film transistor (TFT) on the substrate, the first TFT including a first semiconductor layer, and a second TFT on the substrate, the second TFT including a second semiconductor layer, wherein at least one of the first semiconductor layer and the second semiconductor layer is an oxide semiconductor layer.

According to the aspect of the present specification, the first TFT is a switching TFT or a sampling TFT.

According to the aspect of the present specification, the second TFT is a driving TFT.

According to the aspect of the present specification, the display apparatus may further comprise a first blocking layer disposed under the first semiconductor layer, and a second blocking layer disposed under the second semiconductor layer.

According to the aspect of the present specification, a distance between the first semiconductor layer and the first blocking layer differs from a distance between the second semiconductor layer and the second blocking layer.

According to the aspect of the present specification, a distance between the first semiconductor layer and the first blocking layer is greater than a distance between the second semiconductor layer and the second blocking layer.

According to the aspect of the present specification, the display apparatus may further comprise at least one insulation layer between the first blocking layer and the second blocking layer.

According to the aspect of the present specification, the display apparatus may comprise an emission unit disposed on the first electrode, the emission unit including an emission layer, and a second electrode disposed on the emission unit.

According to the aspect of the present specification, the emission unit is provided in plurality, and a charge generating layer disposed between the plurality of emission units.

According to the aspect of the present specification, a display apparatus may comprise a substrate including an emission portion and a non-emission portion adjacent to the emission portion, a planarization layer disposed on the substrate, the planarization layer including a groove disposed in the non-emission portion, a first electrode disposed in the emission portion and the non-emission portion, a first bank disposed in the non-emission portion and filled in the groove, and a second bank disposed on the first bank.

According to the aspect of the present specification, a thickness of the first bank differs from a thickness of the second bank.

According to the aspect of the present specification, a thickness of the first bank is greater than a thickness of the second bank.

According to the aspect of the present specification, a partial region of the first electrode is disposed between the first bank and the second bank, and the first electrode protrudes from the groove.

According to the aspect of the present specification, the display apparatus may further comprise a spacer overlapping the groove.

According to the aspect of the present specification, the spacer is disposed on the bank.

According to the aspect of the present specification, the display apparatus may further comprise a first thin film transistor (TFT) on the substrate, the first TFT including a first semiconductor layer, and a second TFT on the substrate, the second TFT including a second semiconductor layer, wherein at least one of the first semiconductor layer and the second semiconductor layer is an oxide semiconductor layer.

According to the aspect of the present specification, the first TFT is a switching TFT or a sampling TFT.

According to the aspect of the present specification, the second TFT is a driving TFT.

According to the aspect of the present specification, the display apparatus may further comprise a first blocking layer disposed under the first semiconductor layer, and a second blocking layer disposed under the second semiconductor layer.

According to the aspect of the present specification, a distance between the first semiconductor layer and the first blocking layer differs from a distance between the second semiconductor layer and the second blocking layer.

According to the aspect of the present specification, a distance between the first semiconductor layer and the first blocking layer is greater than a distance between the second semiconductor layer and the second blocking layer.

According to the aspect of the present specification, the display apparatus may further comprise at least one insulation layer between the first blocking layer and the second blocking layer.

According to the aspect of the present specification, the display apparatus may further comprise an emission unit disposed on the first electrode, the emission unit including an emission layer, and a second electrode disposed on the emission unit.

According to the aspect of the present specification, the emission unit is provided in plurality, and a charge generating layer disposed between the plurality of emission units.

A display apparatus according to an aspect of the present disclosure may include a planarization layer including a groove and a bank disposed in the groove, and thus, may solve a problem where the luminance of the display apparatus is reduced.

In a display apparatus according to an aspect of the present disclosure, a bank may include a black material, thereby solving a problem where the luminance of the display apparatus is reduced.

In a display apparatus according to an aspect of the present disclosure, a planarization layer including a groove and a bank filled in the groove may be provided to solve a problem where a thin film transistor is degraded by light, and thus, the thin film transistor may be normally driven, thereby enhancing a sense of beauty, lifetime, and reliability for users.

According to an aspect of the present disclosure, a problem where the luminance of a display apparatus is reduced may be solved, thereby providing a display apparatus which is reduced in power consumption and/or has low power.

The above-described feature, structure, and effect of the present disclosure are included in at least one aspect of the present disclosure, but are not limited to only one aspect. Furthermore, the feature, structure, and effect described in at least one aspect of the present disclosure may be implemented through combination or modification of other aspects by those skilled in the art. Therefore, content associated with the combination and modification should be construed as being within the scope of the present disclosure.

It will be apparent to those skilled in the art that various modifications and variations may be made in the present disclosure without departing from the spirit or scope of the disclosures. Thus, it is intended that the present disclosure covers the modifications and variations of this disclosure provided they come within the scope of the appended claims and their equivalents.

What is claimed is:

1. A display apparatus comprising:
a substrate including an emission portion of a subpixel and a non-emission portion adjacent to the emission portion;
a planarization layer disposed on the substrate, the planarization layer including a groove disposed in the non-emission portion;
a first electrode disposed in the emission portion and the non-emission portion; and
a bank disposed in the non-emission portion and provided in a partial region of the first electrode and in the groove.

2. The display apparatus of claim 1, wherein the bank comprises a black material.

3. The display apparatus of claim 1, wherein the bank fills the groove.

4. The display apparatus of claim 1, wherein the bank surrounds an upper surface, a lower surface, and a lateral surface of the partial region of the first electrode.

5. The display apparatus of claim 1, wherein the bank is disposed under the first electrode.

6. The display apparatus of claim 1, wherein a thickness of the bank is 1.5 μm to 2.5 μm.

7. The display apparatus of claim 1, wherein the partial region of the first electrode protrudes from the groove.

8. The display apparatus of claim 1, wherein the partial region of the first electrode is an end of the first electrode.

9. The display apparatus of claim 1, further comprising a spacer overlapping the groove.

10. The display apparatus of claim 9, wherein the spacer is disposed on the bank.

11. The display apparatus of claim 1, further comprising:
a first thin film transistor (TFT) on the substrate, the first TFT including a first semiconductor layer; and
a second TFT on the substrate, the second TFT including a second semiconductor layer,
wherein at least one of the first semiconductor layer and the second semiconductor layer comprises an oxide semiconductor layer.

12. The display apparatus of claim 11, wherein the first TFT is a switching TFT or a sampling TFT.

13. The display apparatus of claim 11, wherein the second TFT is a driving TFT, and the second TFT comprises an polycrystalline layer.

14. The display apparatus of claim 11, further comprising:
a first light blocking layer disposed under the first semiconductor layer; and
a second light blocking layer disposed under the second semiconductor layer.

15. The display apparatus of claim 14, wherein a distance between the first semiconductor layer and the first light blocking layer differs from a distance between the second semiconductor layer and the second light blocking layer.

16. The display apparatus of claim 14, wherein a distance between the first semiconductor layer and the first blocking layer is greater than a distance between the second semiconductor layer and the second blocking layer.

17. The display apparatus of claim 14, further comprising at least one insulation layer between the first blocking layer and the second blocking layer.

18. The display apparatus of claim 1, further comprising:
an emission unit disposed on the first electrode, the emission unit including an emission layer; and
a second electrode disposed on the emission unit.

19. The display apparatus of claim 18, wherein the emission unit comprises a plurality of layers, and includes a charge generating layer disposed between the plurality of layers.

20. A display apparatus comprising:
a substrate including an emission portion of a subpixel and a non-emission portion adjacent to the emission portion;
a planarization layer disposed on the substrate, the planarization layer including a groove disposed in the non-emission portion;
a first electrode disposed in the emission portion and the non-emission portion;
a first bank disposed in the groove; and
a second bank disposed on the first bank.

21. The display apparatus of claim 20, wherein a thickness of the first bank differs from a thickness of the second bank.

22. The display apparatus of claim 20, wherein a thickness of the first bank is greater than a thickness of the second bank.

23. The display apparatus of claim 20, wherein a partial region of the first electrode is disposed between the first bank and the second bank, and the first electrode protrudes from the groove.

24. The display apparatus of claim 23, wherein the partial region of the first electrode is an end of the first electrode.

25. The display apparatus of claim 20, further comprising a spacer overlapping the groove.

26. The display apparatus of claim 25, wherein the spacer is disposed on the second bank.

27. The display apparatus of claim 20, further comprising:
a first thin film transistor, TFT, on the substrate, the first TFT including a first semiconductor layer; and
a second TFT on the substrate, the second TFT including a second semiconductor layer,
wherein at least one of the first semiconductor layer and the second semiconductor layer is an oxide semiconductor layer.

28. The display apparatus of claim 27, wherein the first TFT is a switching TFT or a sampling TFT.

29. The display apparatus of claim 27, wherein the second TFT is a driving TFT.

30. The display apparatus of claim 27, further comprising:
a first light blocking layer disposed under the first semiconductor layer; and
a second light blocking layer disposed under the second semiconductor layer.

31. The display apparatus of claim 30, wherein a distance between the first semiconductor layer and the first light blocking layer differs from a distance between the second semiconductor layer and the second light blocking layer.

32. The display apparatus of claim 30, wherein a distance between the first semiconductor layer and the first light blocking layer is greater than a distance between the second semiconductor layer and the second light blocking layer.

33. The display apparatus of claim 30, further comprising at least one insulation layer between the first light blocking layer and the second light blocking layer.

34. The display apparatus of claim 20, further comprising:
an emission unit disposed on the first electrode, the emission unit including an emission layer; and
a second electrode disposed on the emission unit.

35. The display apparatus of claim 34, wherein the emission unit comprises a plurality of layers, and includes
a charge generating layer disposed between the plurality of layers.

36. The display apparatus of claim 20, wherein at least one of the first bank and the second bank are configured to block light for a thin film transistor (TFT).
